(19) United States
(12) Patent Application Publication
(10) Pub. No.: US 2025/0385163 A1
(43) Pub. Date: Dec. 18, 2025

(54) SEMICONDUCTOR DEVICE AND POWER CONVERSION DEVICE

(71) Applicant: Mitsubishi Electric Corporation, Tokyo (JP)

(72) Inventors: Wakana MASUDA, Chiyoda-ku, Tokyo (JP); Hodaka ROKUBUICHI, Chiyoda-ku, Tokyo (JP)

(73) Assignee: Mitsubishi Electric Corporation, Tokyo (JP)

(21) Appl. No.: 18/878,094

(22) PCT Filed: Jul. 7, 2022
(86) PCT No.: PCT/JP2022/026975

§ 371 Date: Dec. 23, 2024

(51) Int. Cl. H01L 23/495; H01L 23/00; H01L 23/31; H01L 23/367; H01L 23/40

(52) U.S. Cl. CPC H01L 23/49562; H01L 23/3677; H01L 23/4006; H01L 23/3121; H01L 24/32; H01L 24/48; H01L 24/73; H01L 2224/32245; H01L 2224/48245; H01L 2224/48472; H01L 2224/73265

(57) ABSTRACT

A semiconductor device having high reliability and a power conversion device are obtained. A semiconductor device includes: a semiconductor element; a lead frame; and a sealing resin. The semiconductor element is mounted on the lead frame. The sealing resin seals the semiconductor element and a part of the lead frame. The lead frame includes an inner portion and an external connection terminal portion. The inner portion is in contact with the sealing resin. The external connection terminal portion protrudes outward from a surface of the sealing resin. The lead frame includes a deformable portion. The deformable portion is located at a boundary portion between the inner portion and the external connection terminal portion. The deformable portion is configured such that stress concentrates thereon in order to cause the lead frame to bend. The deformable portion and the surface of the sealing resin intersect with each other.

### TECHNICAL FIELD

The present disclosure relates to a semiconductor device and a power conversion device.

### BACKGROUND ART

A semiconductor device in which a semiconductor element and a part of a lead frame are sealed by a scaling resin has been conventionally known. For example, Japanese Patent Laying-Open No. 2003-31765 discloses a semiconductor device in which a hole for fixation is formed in an external connection terminal portion that is a part of a lead frame extending outside a sealing resin. In the semiconductor device disclosed in Japanese Patent Laying-Open No. 2003-31765, the external connection terminal portion is fixed to an external terminal block and a conductor such as a bus bar by a screw inserted into the hole of the external connection terminal portion. Such a semiconductor device is applied to a power conversion device, for example.

### CITATION LIST

### Patent Literature

PTL 1: Japanese Patent Laying-Open No. 2003-31765

### SUMMARY OF INVENTION

### Technical Problem

In the above-described conventional semiconductor device, when the semiconductor device is arranged such that the hole of the external connection terminal portion overlaps with the terminal block, there may be a gap between the external connection terminal portion and the terminal block. In this case, when the external connection terminal portion and the terminal block are fixed by the screw, the external connection terminal portion is elastically deformed, which results in application of stress to the sealing resin adjacent to the external connection terminal portion. Such stress causes defects such as a fracture of the sealing resin and separation between the sealing resin and the lead frame, which leads to a decrease in reliability of the semiconductor device.

The present disclosure has been made to solve the above-described problem, and an object thereof is to provide a semiconductor device having high reliability and a power conversion device.

### Solution to Problem

A semiconductor device according to the present disclosure includes: a semiconductor element; a lead frame; and a sealing resin. The semiconductor element is mounted on the lead frame. The sealing resin seals the semiconductor element and a part of the lead frame. The lead frame includes an inner portion and an external connection terminal portion. The inner portion is in contact with the scaling resin. The external connection terminal portion protrudes outward from a surface of the sealing resin. The lead frame includes a deformable portion. The deformable portion is located at a boundary portion between the inner portion and the external connection terminal portion. The deformable portion is configured such that stress concentrates thereon in order to cause the lead frame to bend. The deformable portion and the surface of the sealing resin intersect with each other.

A power conversion device according to the present disclosure includes: a main conversion circuit; and a control circuit. The main conversion circuit has the above-described semiconductor device, and converts input power and outputs the converted input power. The control circuit outputs, to the main conversion circuit, a control signal for controlling the main conversion circuit.

### Advantageous Effects of Invention

According to the foregoing, a semiconductor device having high reliability and a power conversion device are obtained.

### BRIEF DESCRIPTION OF DRAWINGS

FIG. 1 is a schematic plan view for describing a configuration of a semiconductor device according to a first embodiment.

FIG. 2 is a schematic cross-sectional view taken along line II-II in FIG. 1.

FIG. 3 is a schematic cross-sectional view for describing the configuration of the semiconductor device shown in FIG. 1.

FIG. 4 is a schematic cross-sectional view for describing a configuration of a modification of the semiconductor device shown in FIG. 1.

FIG. 5 is a schematic cross-sectional view for describing a configuration of a semiconductor device according to a second embodiment.

FIG. 6 is a schematic partial cross-sectional view of a region VI in FIG. 5.

FIG. 7 is a schematic partial cross-sectional view for describing the configuration of the semiconductor device shown in FIG. 5.

FIG. 8 is a schematic partial cross-sectional view for describing a configuration of a first modification of the semiconductor device shown in FIG. 5.

FIG. 9 is a schematic partial cross-sectional view for describing a configuration of a second modification of the semiconductor device shown in FIG. 5.

FIG. 10 is a schematic partial plan view for describing a configuration of a third modification of the semiconductor device shown in FIG. 5.

FIG. 11 is a schematic partial plan view for describing a configuration of a fourth modification of the semiconductor device shown in FIG. 5.

FIG. 12 is a schematic cross-sectional view for describing a configuration of a semiconductor device according to a third embodiment.

FIG. 13 is a schematic partial cross-sectional view for describing the configuration of the semiconductor device shown in FIG. 12.

FIG. 14 is a schematic cross-sectional view for describing a configuration of a modification of the semiconductor device shown in FIG. 12.

FIG. 15 is a schematic partial cross-sectional view for describing the configuration of the semiconductor device shown in FIG. 14.

FIG. 16 is a schematic cross-sectional view for describing a configuration of a semiconductor device according to a fourth embodiment.

FIG. 17 is a block diagram showing a configuration of a power conversion system to which a power conversion device according to a fifth embodiment is applied.

### DESCRIPTION OF EMBODIMENTS

Hereinafter, embodiments of the present disclosure will be described. It should be noted that, unless otherwise specified, the same or corresponding portions in the drawings below are denoted by the same reference numerals and description thereof will not be repeated.

### First Embodiment

### <Configuration of Semiconductor Device>

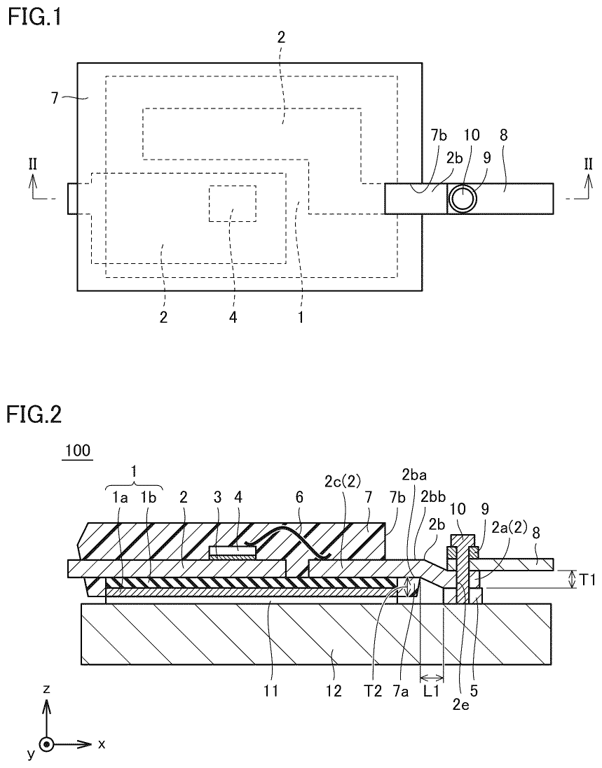

As shown in FIGS. 1 to 3, a semiconductor device 100 according to a first embodiment mainly includes a semiconductor element 4, a lead frame 2, a thermally conductive member 1, a wire 6, a cooler 12, a fixing portion 5, and a sealing resin 7.

Semiconductor element 4 is mounted on lead frame 2. Semiconductor element 4 is mounted on a front surface (upper surface) of lead frame 2 located on the upper side in the z direction. Electrically conductive wire 6 serving as a connection member is arranged to connect an electrode (not shown) of semiconductor element 4 and lead frame 2. Wire 6 is arranged to extend in the x direction in FIG. 2. Thermally conductive member 1 is connected to a back surface of lead frame 2 that is opposite to the upper surface on which semiconductor element 4 is mounted. Thermally conductive member 1, a part of lead frame 2, semiconductor element 4, and wire 6 are sealed by sealing resin 7.

A surface of thermally conductive member 1 is exposed from sealing resin 7. Cooler 12 is connected to the surface of thermally conductive member 1 with a grease 11 interposed therebetween. In a plan view when viewed from the direction perpendicular to the front surface of lead frame 2 on which semiconductor element 4 is mounted, a size of cooler 12 is greater than a size of sealing resin 7. In cooler 12, fixing portion 5 is formed at a position where fixing portion 5 does not overlap with sealing resin 7. As described below, fixing portion 5 is a portion that fixes an external connection terminal portion 2a of lead frame 2.

Lead frame 2 includes an inner portion 2c and external connection terminal portion 2a. Inner portion 2c is a portion that is embedded in sealing resin 7 and is in contact with sealing resin 7. External connection terminal portion 2a is a portion that is continuous to inner portion 2c and protrudes outward from a surface of sealing resin 7. A through hole 2e is formed on the tip side of external connection terminal portion 2a. Through hole 2e is a hole through which a screw 10 serving as a fixing member is inserted. External connection terminal portion 2a is arranged such that through hole 2e overlaps with fixing portion 5. A screw hole into which screw 10 is inserted is formed in fixing portion 5. A bus bar 8 and a washer 9 are arranged to overlap with through hole 2e of external connection terminal portion 2a. A through hole through which screw 10 is inserted is formed in bus bar 8. Bus bar 8 is positioned such that the through hole of bus bar 8 overlaps with through hole 2e of external connection terminal portion 2a. Washer 9 is also arranged to overlap with through hole 2e. Screw 10 is inserted into the hole of washer 9, the through hole of bus bar 8, and through hole 2e of external connection terminal portion 2a, and is fixed to the screw hole of fixing portion 5. In this way, external connection terminal portion 2a is fixed to fixing portion 5 and is connected to bus bar 8.

As shown in FIG. 2, lead frame 2 includes a deformable portion 2b. Deformable portion 2b is located at a boundary portion between inner portion 2c and external connection terminal portion 2a. Deformable portion 2b is configured such that stress concentrates thereon in order to cause lead frame 2 to bend. Therefore, as shown in FIG. 2, the stress when external connection terminal portion 2a is fixed to fixing portion 5 causes lead frame 2 to bend in deformable portion 2b.

A surface of a support portion 7a of sealing resin 7 is in contact with deformable portion 2b such that the surface of support portion 7a of sealing resin 7 and deformable portion 2b intersect with each other. Specifically, deformable portion 2b includes a first surface 2ba and a second surface 2bb. Second surface 2bb is located opposite to first surface 2ba. First surface 2ba is a part of the back surface of lead frame 2 connected to thermally conductive member 1 in deformable portion 2b. Second surface 2bb is a part of the front surface (upper surface) of lead frame 2 to which semiconductor element 4 is connected. In deformable portion 2b, sealing resin 7 is in contact with first surface 2ba and is not in contact with second surface 2bb. That is, since a notch portion 7b is formed in a portion of sealing resin 7 that faces second surface 2bb of deformable portion 2b, second surface 2bb is exposed from sealing resin 7 in deformable portion 2b. On the other hand, support portion 7a of sealing resin 7 is in contact with first surface 2ba of deformable portion 2b. The surface of support portion 7a is in contact with a bending point or is in contact with a neighborhood region within 1 mm from the bending point on first surface 2ba of deformable portion 2b.

Each member that constitutes semiconductor device 100 will be described below.

Thermally conductive member 1 includes a metal foil 1a and an insulating sheet 1b, Insulating sheet 1b is formed on an upper surface of metal foil 1a. That is, thermally conductive member 1 is a stacked body including metal foil 1a and insulating sheet 1b. Thermally conductive member 1 functions as an insulating layer having a high heat dissipation property. Insulating sheet 1b achieves insulation between metal foil 1a and lead frame 2. In addition, heat generated in semiconductor element 4 is dissipated to metal foil 1a through insulating sheet 1b. That is, insulating sheet 1b has a function as a heat transfer member.

A highly thermally conductive member such as, for example, a copper plate, an aluminum plate, a copper foil, or an aluminum foil is used as metal foil 1a. Although not particularly limited, a material of insulating sheet 1b may be an inorganic ceramic material alone, or may be a resin material having at least one of fine particles and a filler dispersed therein. A material of the fine particles and the filler may be an inorganic ceramics material such as, for example, alumina (Al₂O₃), aluminum nitride (AlN), silicon nitride (Si₃N₄), silicon dioxide (SiO₂), boron nitride (BN), diamond (C), silicon carbide (SiC), or boron oxide (B₂O₃). The material of the fine particles and the filler may be a resin material such as a silicone resin or an acrylic resin. The resin having at least one of the fine particles and the filler dispersed therein has an electrically insulating property. Although not particularly limited, the resin having at least one of the fine particles and the filler dispersed therein may be mainly composed of an epoxy resin, a polyimide resin, a silicone resin, or an acrylic resin.

As shown in FIG. 2, lead frame 2 having an arbitrary wiring structure (wiring circuit) formed thereon is provided on thermally conductive member 1. Lead frame 2 includes the front surface and the back surface. The back surface of lead frame 2 including first surface 2ba of deformable portion 2b is connected to insulating sheet 1b of thermally conductive member 1. On the front surface of lead frame 2 including second surface 2bb of deformable portion 2b, a back surface electrode (not shown) of semiconductor element 4 is joined to the wiring circuit with a solder 3 as a joining member interposed therebetween.

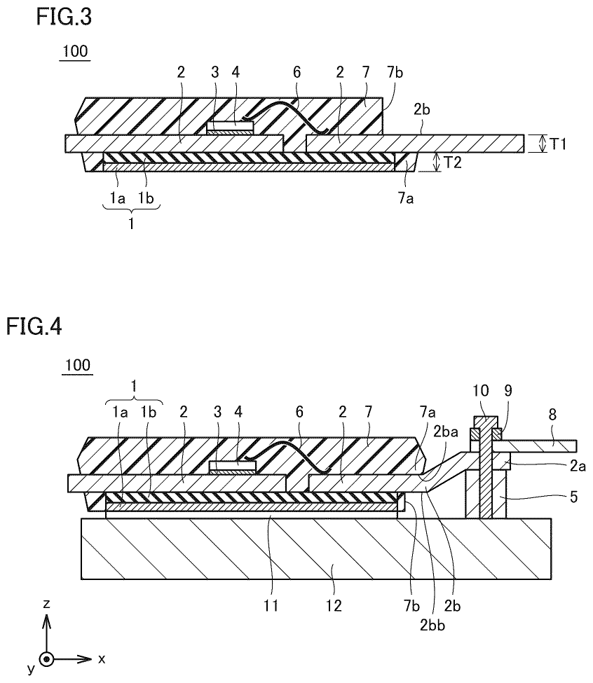

A portion of lead frame 2 protruding from sealing resin 7 is screwed, as external connection terminal portion 2a, to bus bar 8 and fixing portion 5 serving as a terminal block. As shown in FIG. 3, before external connection terminal portion 2a is fixed to fixing portion 5, external connection terminal portion 2a is formed to extend linearly from the surface of sealing resin 7. As shown in FIG. 2, when fixing portion 5 is integrated with cooler 12, a height difference may occur between a lower surface of external connection terminal portion 2a and an upper surface of fixing portion 5 due to dimensional tolerances of the members. For example, the lower surface of external connection terminal portion 2a may be located above the upper surface of fixing portion 5 with a space therebetween. When external connection terminal portion 2a is screwed onto fixing portion 5 by screw 10 in this state, external connection terminal portion 2a is deformed to bend in the direction of the upper surface of fixing portion 5. As a result, the lower surface of external connection terminal portion 2a comes into contact with the upper surface of fixing portion 5 as shown in FIG. 2. At this time, a resin fracture of sealing resin 7 and separation at an interface between sealing resin 7 and external connection terminal portion 2a can be suppressed because external connection terminal portion 2a has deformable portion 2b on which stress concentrates during screwing.

Various types of semiconductor elements can be applied as semiconductor element 4. For example, a diode used in a converter portion that converts input alternating current (AC) power into direct current (DC) power, a bipolar transistor used in an inverter portion that converts DC power into AC power, an insulated gate bipolar transistor (IGBT), a metal oxide semiconductor field effect transistor (MOSFET), a gate turn-off thyristor (GTO) or the like can be used as semiconductor element 4.

Sealing resin 7 ensures the insulating property between the sealed members such as semiconductor element 4 and lead frame 2, and functions as a case of semiconductor device 100. Sealing resin 7 seals lead frame 2 and semiconductor element 4 integrally. Transfer molding, injection molding, compression molding or the like can, for example, be used as a molding method for sealing resin 7. In addition, a filler-containing epoxy resin, a filler-containing phenol resin or the like can, for example, be used as a material of sealing resin 7.

Next, a manufacturing method for semiconductor device 100 according to the present embodiment configured as described above will be described.

First, the step of preparing the members such as lead frame 2 and semiconductor element 4 that constitute semiconductor device 100 is performed. Prepared lead frame 2 has a plurality of portions connected to each other by a frame portion located at an outer perimeter portion. Next, the step of connecting the members is performed. Specifically, semiconductor element 4 is joined onto the front surface of lead frame 2 with solder 3 interposed therebetween. Next, wire 6 that connects the wiring circuit formed on lead frame 2 and semiconductor element 4 by wire bonding is formed.

Next, the step of sealing, by sealing resin 7, lead frame 2 after the above-described steps are performed (resin sealing step) is performed. In the resin sealing step, thermally conductive member 1 and lead frame 2 that has completed the process up to wire bonding through the above-described steps are arranged in a mold. Thereafter, a resin serving as sealing resin 7 is injected into the mold. In this step, a molding method such as transfer molding, compression molding or injection molding can be applied. After molding, a part of lead frame 2 is cut. Specifically, the frame portion is cut and removed from the outer perimeter portion of lead frame 2, for example. In this way, semiconductor device 100 shown in FIG. 3 is obtained.

Next, semiconductor device 100 thus formed is assembled to cooler 12 with grease 11 interposed therebetween. Thereafter, semiconductor device 100 is mounted in a power conversion device, for example. External connection terminal portion 2a is electrically connected (fastened) to bus bar 8 in the power conversion device as shown in FIG. 2. As shown in FIGS. 1 and 2, a structure of a connection portion of external connection terminal portion 2a and bus bar 8 is a screwed structure using washer 9 and screw 10. However, the present disclosure is not limited thereto and other structures may be adopted. For example, external connection terminal portion 2a and bus bar 8 may be connected by ultrasonic joining or the like.

For example, the case where when a thickness T1 of external connection terminal portion 2a is 0.5 mm, a distance between sealing resin 7 and bus bar 8 is equal to or shorter than 3.5 mm will be considered. In this case, a distance L1 between sealing resin 7 and fixing portion 5 is substantially equal to or shorter than 3.5 mm. That is, the case where when external connection terminal portion 2a is fixed to fixing portion 5, distance L1 between fixing portion 5 and the surface of sealing resin 7 is seven times or less thickness T1 of external connection terminal portion 2a will be considered.

When the upper surface of fixing portion 5 is located below the lower surface of external connection terminal portion 2a in this state, notch portion 7b, which is a portion where there is no sealing resin 7, is formed in the upper surface (surface that is continuous to second surface 2bb of deformable portion 2b) of external connection terminal portion 2a in resin-scaled semiconductor device 100. In notch portion 7b, at least a part of the upper surface of external connection terminal portion 2a is not covered with sealing resin 7. The portion of the upper surface of external connection terminal portion 2a that is not in contact with sealing resin 7 may extend to a position that is more inner by, for example, approximately 3.5 mm than the surface (edge portion) of support portion 7a of sealing resin 7 that is in contact with the lower surface of external connection terminal portion 2a. Notch portion 7b, which is a portion where there is no sealing resin 7, is preferably formed only in the region located on external connection terminal portion 2a. However, notch portion 7b may spread in a direction intersecting with an extension direction of external connection terminal portion 2a (e.g., a direction perpendicular to the sheet of FIG. 2). In this case, a bottom surface of notch portion 7b may be flush with the upper surface of external connection terminal portion 2a. For example, a side wall of notch portion 7b shown in FIG. 2 may be formed over the entire width of sealing resin 7 in the direction perpendicular to the sheet of FIG. 2. When thickness T1 of external connection terminal portion 2a is 0.5 mm, a thickness T2 of support portion 7a of sealing resin 7 located to be in contact with the lower surface of external connection terminal portion 2a is preferably equal to or greater than 1.25 mm. That is, in a thickness direction that is a direction from first surface 2ba to second surface 2bb, thickness T2 of support portion 7a, which is a portion of sealing resin 7 that is in contact with first surface 2ba, is 2.5 times or more thickness T1 of external connection terminal portion 2a. Thickness T1 of external connection terminal portion 2a may be equal to or greater than 0.5 mm.

When external connection terminal portion 2a is connected (fastened) to fixing portion 5 and bus bar 8, external connection terminal portion 2a bends in a fastening direction (direction toward fixing portion 5: −z direction) in deformable portion 2b as shown in FIG. 2. At this time, an end (corner portion where the surface of sealing resin 7 and an upper surface of support portion 7a intersect with each other) of support portion 7a comes into contact with deformable portion 2b from the lower surface side, and thus, stress concentrates on deformable portion 2b. That is, deformable portion 2b is a starting point of deformation. Therefore, deformable portion 2b is deformed (bends) preferentially, which makes it possible to suppress the application of excessive stress to an interface between lead frame 2 and sealing resin 7 other than deformable portion 2b. Therefore, the occurrence of a fracture of sealing resin 7 and separation at the connection interface between sealing resin 7 and external connection terminal portion 2a can be suppressed.

Semiconductor device 100 configured as described above has such a shape that support portion 7a of sealing resin 7 is present on one surface of external connection terminal portion 2a, and the contact point between the end of support portion 7a of sealing resin 7 and external connection terminal portion 2a is a starting point of deformation (deformable portion 2b). Therefore, stress concentrates on deformable portion 2b, and thus, deformable portion 2b is deformed preferentially, which makes it possible to suppress a resin fracture of sealing resin 7 and separation at the interface between sealing resin 7 and external connection terminal portion 2a in the other portions. Therefore, it is possible to suppress the ingress of water into semiconductor device 100 through a portion having the above-described resin fracture or separation at the interface, without increasing a length of external connection terminal portion 2a. In addition, it is also possible to suppress poor insulation caused by the progress of the above-described resin fracture and separation at the interface. As a result, it is possible to suppress an increase in size of semiconductor device 100 while enhancing the reliability of semiconductor device 100.

### Modification

Semiconductor device 100 shown in FIG. 4 basically has the same configuration as that of semiconductor device 100 shown in FIGS. 1 and 2. However, semiconductor device 100 shown in FIG. 4 is different from semiconductor device 100 shown in FIGS. 1 and 2 in terms of the relative positional relationship between the upper surface of fixing portion 5 and the lower surface of external connection terminal portion 2a and the shape of sealing resin 7. That is, in semiconductor device 100 shown in FIG. 4, a height of the upper surface of fixing portion 5 from a surface of cooler 12 is higher than a height of the lower surface of external connection terminal portion 2a from the surface of cooler 12. Therefore, in FIG. 4, by fixing external connection terminal portion 2a to fixing portion 5, external connection terminal portion 2a bends to the side away from cooler 12 (side of the upper surface of lead frame 2 on which semiconductor element 4 is mounted).

In FIG. 4, first surface 2ba of deformable portion 2b is included in the upper surface of lead frame 2, and second surface 2bb is included in the lower surface of lead frame 2. In addition, notch portion 7b in sealing resin 7 is formed on the lower surface side of lead frame 2. Support portion 7a of sealing resin 7 is in contact with the upper surface (surface on which semiconductor element 4 is mounted) of lead frame 2. As described above, the structure in the vicinity of deformable portion 2b in semiconductor device 100 shown in FIG. 4 is reversed in the up-down direction from that in semiconductor device 100 shown in FIG. 2. In this case as well, notch portion 7b of scaling resin 7 is formed on the opposite side of the bending direction of deformable portion 2b, which makes it possible to suppress the occurrence of a problem such as breakage of sealing resin 7 in a region located opposite to the deformation direction of deformable portion 2b (region of the lower surface of lead frame 2 where lead frame 2 is exposed from notch portion 7b).

### Functions

Semiconductor device 100 according to the present disclosure includes: semiconductor element 4; lead frame 2; and sealing resin 7. Semiconductor element 4 is mounted on lead frame 2. Sealing resin 7 seals semiconductor element 4 and a part of lead frame 2. Lead frame 2 includes inner portion 2c and external connection terminal portion 2a. Inner portion 2c is in contact with sealing resin 7. External connection terminal portion 2a protrudes outward from a surface of sealing resin 7. Lead frame 2 includes deformable portion 2b. Deformable portion 2b is located at a boundary portion between inner portion 2c and external connection terminal portion 2a. Deformable portion 2b is configured such that stress concentrates thereon in order to cause lead frame 2 to bend. Deformable portion 2b and the surface of sealing resin 7 intersect with each other.

With such a configuration, when the external force is applied to external connection terminal portion 2a, deformable portion 2b is preferentially deformed by the external force. This makes it possible to suppress the occurrence of such a problem that the external force acts on the contact portion between inner portion 2c of lead frame 2 and sealing resin 7, which leads to separation or breakage of sealing resin 7 at the contact portion. Thus, the reliability of semiconductor device 100 can be enhanced. In addition, since deformable portion 2b and the surface of sealing resin 7 intersect with each other, i.e., deformable portion 2b is arranged to partially overlap with the surface of sealing resin 7, the dimension of external connection terminal portion 2a can be reduced, as compared with when deformable portion 2b is formed at a position distant from sealing resin 7 in external connection terminal portion 2a. Therefore, the present disclosure is also applicable to a small-sized semiconductor device.

In semiconductor device 100 described above, deformable portion 2b includes first surface 2ba and second surface 2bb. Second surface 2bb is located opposite to first surface 2ba. In deformable portion 2b, sealing resin 7 is in contact with first surface 2ba and is not in contact with second surface 2bb.

In this case, sealing resin 7 is in contact with first surface 2ba of deformable portion 2b, and thus, support portion 7a of sealing resin 7 is arranged only on one surface (first surface 2ba) of deformable portion 2b. Therefore, when the external force is applied to the first surface 2ba side such that external connection terminal portion 2a bends, support portion 7a of sealing resin 7 supports (presses) deformable portion 2b from the first surface 2ba side. As a result, lead frame 2 can easily bend in deformable portion 2b. In addition, since sealing resin 7 is not in contact with second surface 2bb of deformable portion 2b, there does not arise such a problem that when deformable portion 2b bends, second surface 2bb of deformable portion 2b applies stress to sealing resin 7, which causes breakage of sealing resin 7.

In semiconductor device 100 described above, in a thickness direction that is a direction from first surface 2ba to second surface 2bb, thickness T2 of support portion 7a, which is a portion of sealing resin 7 that is in contact with first surface 2ba, is 2.5 times or more thickness T1 of external connection terminal portion 2a.

In this case, support portion 7a of sealing resin 7 has sufficient thickness T2, and thus, support portion 7a presses deformable portion 2b of lead frame 2, which makes it possible to promote concentration of stress on deformable portion 2b and deformation.

In semiconductor device 100 described above, when external connection terminal portion 2a is fixed to fixing portion 5 located outside sealing resin 7, distance L1 between fixing portion 5 and the surface of sealing resin 7 is seven times or less thickness T1 of external connection terminal portion 2a.

As described above, by applying the above-described configuration according to the present disclosure to semiconductor device 100 in which distance L1 between fixing portion 5 and the surface of sealing resin 7 is relatively small, separation between lead frame 2 and sealing resin 7 and breakage of sealing resin 7 can be effectively suppressed even when external connection terminal portion 2a and fixing portion 5 are positionally displaced.

In semiconductor device 100 described above, thickness T1 of external connection terminal portion 2a is equal to or greater than 0.5 mm. In this case, external connection terminal portion 2a has some degree of rigidity, and thus, when stress is applied to external connection terminal portion 2a, the stress tends to be transferred to sealing resin 7 that is in contact with lead frame 2. However, by adopting the configuration according to the present disclosure, breakage of sealing resin 7 and the like caused by the stress can be effectively suppressed.

### Second Embodiment

### <Configuration of Semiconductor Device>

A semiconductor device 200 shown in FIGS. 5 to 7 basically has the same configuration as that of semiconductor device 100 shown in FIGS. 1 and 2. However, semiconductor device 200 shown in FIGS. 5 to 7 is different from semiconductor device 100 shown in FIGS. 1 and 2 in terms of the shapes of deformable portion 2b and sealing resin 7. That is, in semiconductor device 200 shown in FIGS. 5 to 7, in deformable portion 2b, a recessed portion 21 is formed in the upper surface (surface on which semiconductor element 4 is mounted) of lead frame 2 such that a cross-sectional area in a cross section perpendicular to the extension direction of external connection terminal portion 2a is locally reduced. Recessed portion 21 serving as deformable portion 2b is formed at a position where recessed portion 21 overlaps with the surface of sealing resin 7, such that recessed portion 21 and the surface of sealing resin 7 intersect with each other. That is, in semiconductor device 200 shown in FIGS. 5 to 7, notch portion 7b of scaling resin 7 as shown in FIGS. 1 and 2 is not formed. Recessed portion 21 is formed in the front surface (upper surface) of lead frame 2 located opposite to the bending direction of lead frame 2 (lower side where thermally conductive member 1 is located in FIG. 5).

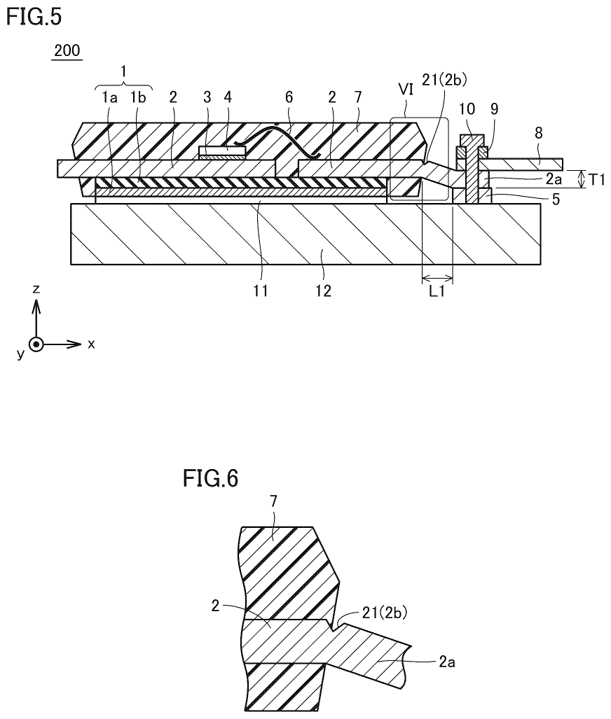

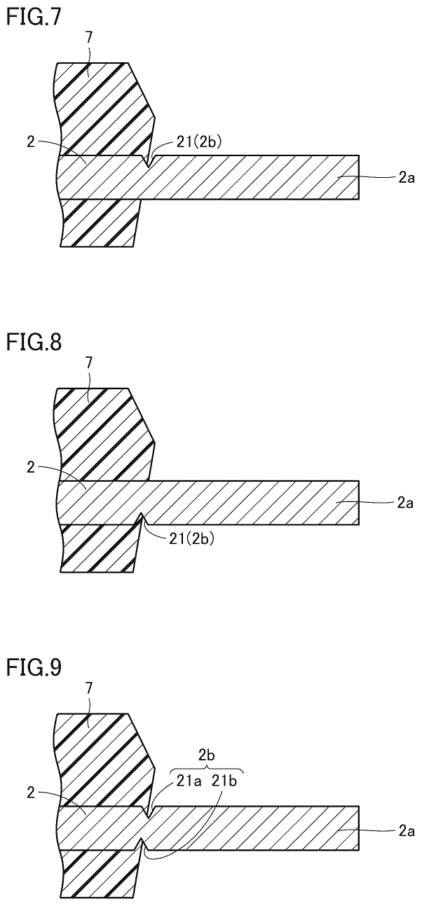

Recessed portion 21 is, for example, a notch portion formed by partially removing lead frame 2. Recessed portion 21 may be formed by knurling, for example. Such recessed portion 21 is formed in semiconductor device 200 before lead frame 2 is bent as shown in FIG. 7. Then, when external connection terminal portion 2a in semiconductor device 200 is connected (fastened) to fixing portion 5 and bus bar 8 as shown in FIG. 5, external connection terminal portion 2a bends in the fastening direction (direction toward fixing portion 5) at the portion where recessed portion 21 serving as deformable portion 2b is formed. At this time, lead frame 2 easily bends at the portion of lead frame 2 having the locally reduced cross-sectional area (portion where recessed portion 21 is formed) because recessed portion 21 is formed. Furthermore, since sealing resin 7 is in contact with a part of recessed portion 21, a part of recessed portion 21 is fixed by sealing resin 7. Therefore, lead frame 2 bends more easily at the portion where recessed portion 21 is formed. A cross-sectional shape of recessed portion 21 may be any shape, and may be a V shape as shown in FIG. 6 or may be a U shape. An inner perimeter surface of recessed portion 21 may be formed of a curved surface. Recessed portion 21 may be formed entirely in the width direction orthogonal to the extension direction of lead frame 2, or may be formed partially in the width direction.

As shown in FIG. 5, thickness T1 of external connection terminal portion 2a is, for example, 1 mm. Distance L1 between sealing resin 7 and fixing portion 5, or a distance between sealing resin 7 and bus bar 8 is equal to or shorter than 7 mm, for example.

Semiconductor device 200 described above can be basically manufactured by the same manufacturing method as the manufacturing method for semiconductor device 100 according to the first embodiment. Specifically, by performing the step of preparing the members that constitute semiconductor device 200, the step of connecting the members, and the step of sealing by sealing resin 7, semiconductor device 200 having the structure shown in FIG. 7 is obtained. Semiconductor device 200 is assembled to cooler 12. Thereafter, semiconductor device 200 is mounted in an electric device such as a power conversion device, for example.

External connection terminal portion 2a is electrically connected (fastened) to bus bar 8 in the power conversion device as shown in FIG. 5. Similarly to semiconductor device 100 according to the first embodiment, the structure of the connection portion of external connection terminal portion 2a and bus bar 8 is the screwed structure using washer 9 and screw 10.

When external connection terminal portion 2a is connected (fastened) to fixing portion 5 and bus bar 8 in a case where the upper surface of fixing portion 5 is located below the lower surface of external connection terminal portion 2a, external connection terminal portion 2a bends in the fastening direction (direction toward fixing portion 5) in deformable portion 2b as shown in FIG. 5. At this time, the cross-sectional area is locally reduced because recessed portion 21 is formed in deformable portion 2b, and thus, deformable portion 2b has a locally reduced strength. In addition, recessed portion 21 of deformable portion 2b is partially in contact with sealing resin 7. That is, recessed portion 21 is partially (e.g., a half) included in sealing resin 7. Therefore, deformable portion 2b can be easily deformed. Thus, external connection terminal portion 2a can be fastened to bus bar 8 without applying, to sealing resin 7, stress that may cause a resin fracture and separation at the interface between sealing resin 7 and lead frame 2.

### Modification

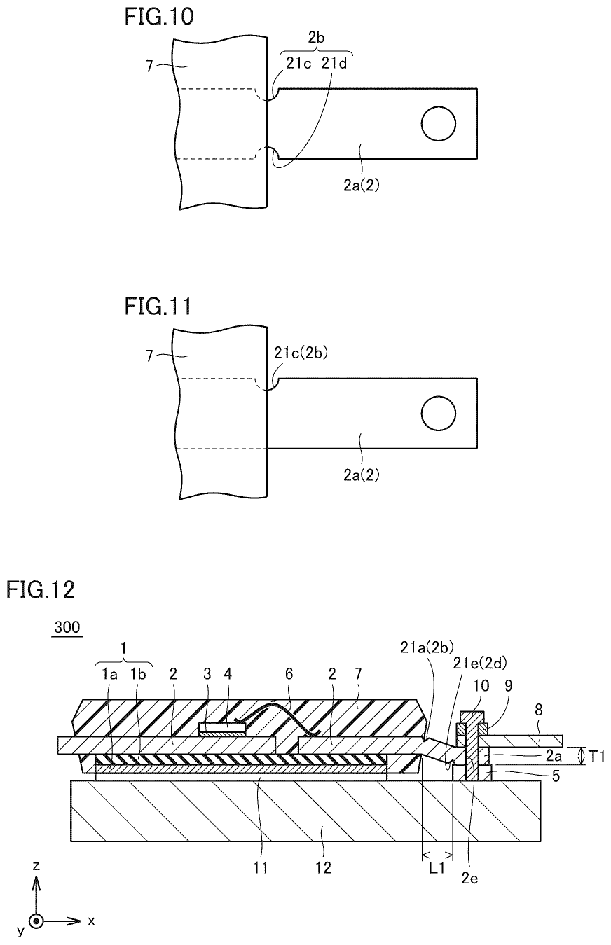

As shown in FIGS. 8 to 11, recessed portion 21 formed as deformable portion 2b in lead frame 2 may be formed on a surface other than the upper surface of lead frame 2. FIGS. 8 and 9 are schematic partial cross-sectional views showing first and second modifications of semiconductor device 200 shown in FIGS. 5 to 7. FIGS. 8 to 11 correspond to FIG. 7. FIGS. 10 and 11 are schematic partial plan views showing third and fourth modifications of semiconductor device 200 shown in FIGS. 5 to 7. Each of FIGS. 10 and 11 shows a configuration of deformable portion 2b in a plan view when viewed from the direction perpendicular to the upper surface of lead frame 2.

The first modification of semiconductor device 200 shown in FIG. 8 basically has the same configuration as that of semiconductor device 200 shown in FIGS. 5 to 7. However, the first modification of semiconductor device 200 shown in FIG. 8 is different from semiconductor device 200 shown in FIGS. 5 to 7 in terms of the arrangement of recessed portion 21 in lead frame 2. In semiconductor device 200 shown in FIG. 8, recessed portion 21 serving as deformable portion 2b is formed in the lower surface of lead frame 2. A recessed portion is not formed in the upper surface of lead frame 2. In FIG. 8 as well, recessed portion 21 is arranged at a position where recessed portion 21 partially overlaps with the surface of sealing resin 7.

The second modification of semiconductor device 200 shown in FIG. 9 basically has the same configuration as that of semiconductor device 200 shown in FIGS. 5 to 7. However, the second modification of semiconductor device 200 shown in FIG. 9 is different from semiconductor device 200 shown in FIGS. 5 to 7 in terms of the configuration of recessed portion 21 in lead frame 2. In semiconductor device 200 shown in FIG. 9, a recessed portion 21a and a recessed portion 21b are formed in lead frame 2 as deformable portion 2b. Recessed portion 21a is formed in the upper surface of lead frame 2. Recessed portion 21b is formed in the lower surface of lead frame 2. In FIG. 9 as well, each of recessed portion 21a and recessed portion 21b is arranged at a position where each of recessed portion 21a and recessed portion 21b partially overlaps with the surface of sealing resin 7. In FIG. 9, recessed portion 21a and recessed portion 21b are formed at positions where recessed portion 21a and recessed portion 21b face each other in the thickness direction of lead frame 2. However, in a plan view when viewed from the direction perpendicular to the upper surface of lead frame 2, recessed portion 21a and recessed portion 21b are arranged in a displaced manner such that recessed portion 21a and recessed portion 21b only partially overlap with each other.

The third modification of semiconductor device 200 shown in FIG. 10 basically has the same configuration as that of semiconductor device 200 shown in FIGS. 5 to 7. However, the third modification of semiconductor device 200 shown in FIG. 10 is different from semiconductor device 200 shown in FIGS. 5 to 7 in terms of the arrangement of deformable portion 2b in lead frame 2. In semiconductor device 200 shown in FIG. 10, a recessed portion 21c and a recessed portion 21d are formed in lead frame 2 as deformable portion 2b. Recessed portion 21c is formed in one of two side surfaces that connect the upper surface and the lower surface of lead frame 2. Recessed portion 21d is formed in the other of the two side surfaces of lead frame 2. In FIG. 10 as well, each of recessed portion 21c and recessed portion 21d is arranged at a position where each of recessed portion 21c and recessed portion 21d partially overlaps with the surface of sealing resin 7. In FIG. 10, recessed portion 21c and recessed portion 21d are formed at positions where recessed portion 21c and recessed portion 21d face each other in the width direction, which is a direction perpendicular to the thickness direction of lead frame 2 and a direction perpendicular to the extension direction of external connection terminal portion 2a.

The fourth modification of semiconductor device 200 shown in FIG. 11 basically has the same configuration as that of semiconductor device 200 shown in FIG. 10. However, the fourth modification of semiconductor device 200 shown in FIG. 11 is different from semiconductor device 200 shown in FIG. 10 in terms of the configuration of deformable portion 2b in lead frame 2. In semiconductor device 200 shown in FIG. 11, one recessed portion 21c is formed in lead frame 2 as deformable portion 2b. Recessed portion 21c is formed in one of two side surfaces that connect the upper surface and the lower surface of lead frame 2. A recessed portion is not formed in the other of the two side surfaces of lead frame 2. In FIG. 11 as well, recessed portion 21c is arranged at a position where recessed portion 21c partially overlaps with the surface of sealing resin 7.

Although one or two recessed portions serving as deformable portion 2b may be formed in lead frame 2 as described above, the number of recessed portions may be three or more. For example, the recessed portions may be formed in three or four surfaces of the upper surface, the lower surface, one side surface, and the other side surface of lead frame 2. Recessed portion 21a to recessed portion 21d are preferably formed in a set of surfaces of lead frame 2 that face each other.

### Functions

In semiconductor device 200 described above, in deformable portion 2b, recessed portion 21 is formed such that a cross-sectional area in a cross section perpendicular to an extension direction of external connection terminal portion 2a is locally reduced. Recessed portion 21 and the surface of sealing resin 7 intersect with each other.

In this case, when the external force is applied to external connection terminal portion 2a, lead frame 2 can be easily deformed in recessed portion 21 serving as deformable portion 2b. In addition, since recessed portion 21 and the surface of sealing resin 7 intersect with each other, recessed portion 21 is partially fixed by sealing resin 7. Therefore, a region where stress concentrates can be easily formed within recessed portion 21, which allows lead frame 2 to reliably bend in recessed portion 21.

In semiconductor device 200 described above, when external connection terminal portion 2a is fixed to fixing portion 5 located outside sealing resin 7, distance L1 between fixing portion 5 and the surface of sealing resin 7 is seven times or less thickness T1 of external connection terminal portion 2a.

As described above, by applying the configuration of the semiconductor device according to the second embodiment to semiconductor device 200 in which distance L1 between fixing portion 5 and the surface of sealing resin 7 is relatively small, lead frame 2 easily bends in recessed portion 21 even when external connection terminal portion 2a and fixing portion 5 are positionally displaced. Therefore, breakage of scaling resin 7 and the like can be effectively suppressed.

In semiconductor device 200 described above, thickness T1 of external connection terminal portion 2a is equal to or greater than 0.5 mm. In this case, external connection terminal portion 2a has some degree of rigidity, and thus, when stress is applied to external connection terminal portion 2a, the stress tends to be transferred to sealing resin 7 that is in contact with lead frame 2. However, by adopting the configuration according to the present disclosure, breakage of sealing resin 7 and the like caused by the stress can be effectively suppressed because lead frame 2 easily bends in recessed portion 21.

### Third Embodiment

### <Configuration of Semiconductor Device>

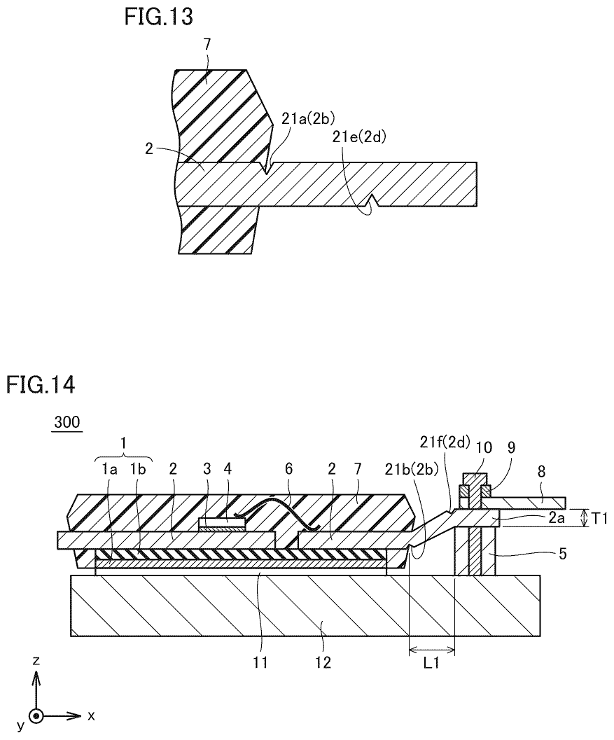

A semiconductor device 300 shown in FIGS. 12 and 13 basically has the same configuration as that of semiconductor device 200 shown in FIGS. 5 to 7. However, semiconductor device 300 shown in FIGS. 12 and 13 is different from semiconductor device 200 shown in FIGS. 5 to 7 in that an additional deformable portion 2d is formed in external connection terminal portion 2a of lead frame 2. In semiconductor device 300 shown in FIGS. 12 and 13, additional deformable portion 2d is formed in external connection terminal portion 2a at a position that is more distant than deformable portion 2b when viewed from sealing resin 7. Additional deformable portion 2d is a recessed portion 21e formed in the lower surface of external connection terminal portion 2a. By locally reducing the cross-sectional area of external connection terminal portion 2a, additional deformable portion 2d is configured such that stress concentrates thereon in order to cause external connection terminal portion 2a to bend.

As shown in FIG. 12, through hole 2e through which screw 10 serving as a fixing member is inserted is formed in external connection terminal portion 2a. Through hole 2e is formed at a position that is more distant than additional deformable portion 2d when viewed from sealing resin 7. Similarly to semiconductor device 200 shown in FIG. 5, screw 10 serving as a fixing member is inserted into the hole of washer 9, the through hole of bus bar 8, and through hole 2e of external connection terminal portion 2a, and is fixed to the screw hole of fixing portion 5. In a state where screw 10 is inserted through through hole 2e, recessed portion 21e serving as additional deformable portion 2d is arranged at a position where recessed portion 21e overlaps with an outer circumference of washer 9. External connection terminal portion 2a bends downward (direction toward fixing portion 5) in deformable portion 2b. In addition, external connection terminal portion 2a bends in a direction (direction away from fixing portion 5) opposite to the deformation direction of deformable portion 2b in additional deformable portion 2d. A portion of external connection terminal portion 2a located on the tip side with respect to additional deformable portion 2d (portion where through hole 2e is formed) is arranged to extend in a direction along the upper surface of fixing portion 5.

Semiconductor device 300 described above can be basically manufactured by the same manufacturing method as the manufacturing method for semiconductor device 200 according to the second embodiment. Specifically, by performing the step of preparing the members that constitute semiconductor device 300, the step of connecting the members, and the step of sealing by sealing resin 7, semiconductor device 300 having the structure shown in FIG. 13 is obtained. Semiconductor device 300 is assembled to cooler 12. Thereafter, semiconductor device 300 is mounted in an electric device such as a power conversion device, for example.

External connection terminal portion 2a is electrically connected (fastened) to bus bar 8 in the power conversion device as shown in FIG. 12. Similarly to semiconductor device 100 according to the second embodiment, the structure of the connection portion of external connection terminal portion 2a and bus bar 8 is the screwed structure using washer 9 and screw 10.

When external connection terminal portion 2a is connected (fastened) to fixing portion 5 and bus bar 8 in a case where the upper surface of fixing portion 5 is located below the lower surface of external connection terminal portion 2a, external connection terminal portion 2a bends in the fastening direction (direction toward fixing portion 5) in deformable portion 2b as shown in FIG. 12. Furthermore, in additional deformable portion 2d, external connection terminal portion 2a bends in the direction opposite to the bending direction in deformable portion 2b. At this time, the cross-sectional area is locally reduced because recessed portion 21e is formed in additional deformable portion 2d, and thus, additional deformable portion 2d has a locally reduced strength. Therefore, additional deformable portion 2d can be easily deformed. Thus, external connection terminal portion 2a can be fastened to bus bar 8 without excessively applying, to sealing resin 7, stress generated when external connection terminal portion 2a is connected to bus bar 8 by screw 10.

A cross-sectional shape of recessed portion 21e that constitutes additional deformable portion 2d may be any shape, and may be a V shape as shown in FIG. 12 or may be a U shape. An inner perimeter surface of recessed portion 21e may be formed of a curved surface. Recessed portion 21e may be formed entirely in the width direction orthogonal to the extension direction of external connection terminal portion 2a, or may be formed partially in the width direction. A plurality of recessed portions 21e may be formed in the lower surface of external connection terminal portion 2a. Although one or two recessed portions serving as additional deformable portion 2d may be formed in external connection terminal portion 2a, the number of recessed portions may be three or more. For example, recessed portions 21e may be formed in three or four surfaces of the upper surface, the lower surface, one side surface, and the other side surface of external connection terminal portion 2a. Recessed portions 21e are preferably formed in a set of surfaces of external connection terminal portion 2a that face each other. Recessed portion 21e is, for example, a notch portion formed by partially removing external connection terminal portion 2a. Recessed portion 21e may be formed by knurling, for example. Although recessed portion 21b and recessed portion 21e are formed in the different surfaces, of the upper surface and the lower surface of lead frame 2, recessed portion 21b and recessed portion 21e may be formed in the same surface.

### Modification

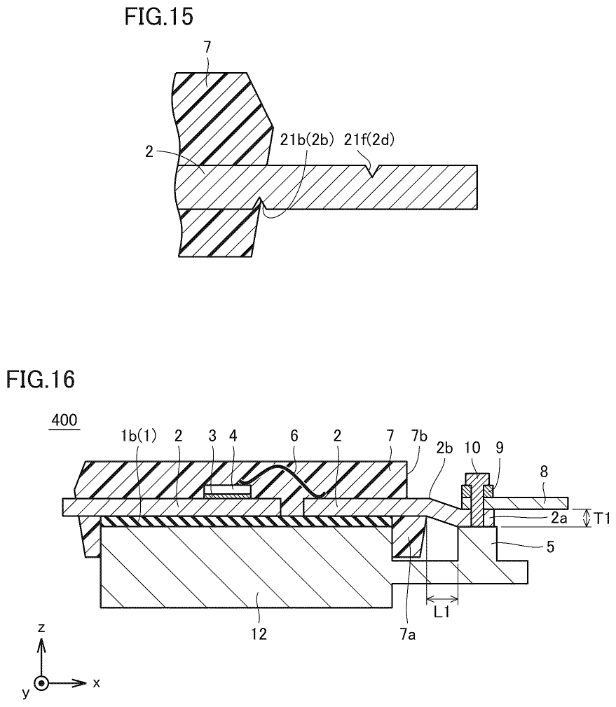

Semiconductor device 300 shown in FIGS. 14 and 15 basically has the same configuration as that of semiconductor device 300 shown in FIGS. 12 and 13. However, semiconductor device 300 shown in FIGS. 14 and 15 is different from semiconductor device 300 shown in FIGS. 12 and 13 in terms of the relative positional relationship between the upper surface of fixing portion 5 and the lower surface of external connection terminal portion 2a and the arrangement of deformable portion 2b and additional deformable portion 2d. FIG. 14 corresponds to FIG. 12, and FIG. 15 corresponds to FIG. 13.

In semiconductor device 300 shown in FIGS. 14 and 15, recessed portion 21b is formed in the lower surface (surface that faces thermally conductive member 1) of lead frame 2 as deformable portion 2b. In addition, a recessed portion 21f is formed in the upper surface (surface on the side where semiconductor element 4 is located) of external connection terminal portion 2a as additional deformable portion 2d. That is, the arrangement of deformable portion 2b and additional deformable portion 2d in semiconductor device 300 shown in FIGS. 14 and 15 is reversed from that in semiconductor device 300 shown in FIGS. 12 and 13.

In semiconductor device 300 shown in FIGS. 14 and 15, a height of the upper surface of fixing portion 5 from the surface of cooler 12 is higher than a height of the lower surface of external connection terminal portion 2a from the surface of cooler 12. Therefore, in FIG. 14, by fixing external connection terminal portion 2a to fixing portion 5, external connection terminal portion 2a bends to the side away from cooler 12 (side of the upper surface of lead frame 2 on which semiconductor element 4 is mounted: +z direction) in deformable portion 2b. In addition, external connection terminal portion 2a bends to the direction toward cooler 12 (−z direction) in additional deformable portion 2d.

As described above, the structure of deformable portion 2b and additional deformable portion 2d in semiconductor device 300 shown in FIGS. 14 and 15 is reversed in the up-down direction from that in semiconductor device 300 shown in FIGS. 12 and 13. In this case as well, the same effect as that of semiconductor device 300 shown in FIGS. 12 and 13 can be obtained.

### Functions

In semiconductor device 300 described above, external connection terminal portion 2a includes additional deformable portion 2d. Additional deformable portion 2d is formed in external connection terminal portion 2a at a position that is more distant than deformable portion 2b when viewed from sealing resin 7. Additional deformable portion 2d is configured such that stress concentrates thereon in order to cause external connection terminal portion 2a to bend.

In this case, the portions (deformable portion 2b and additional deformable portion 2d) that can bend to absorb the stress applied to external connection terminal portion 2a are formed at at least two locations in external connection terminal portion 2a. Therefore, the stress is easily absorbed by bending of these portions, which makes it possible to suppress breakage of sealing resin 7 and the like caused by the stress.

In semiconductor device 300 described above, through hole 2e is formed in external connection terminal portion 2a. Through hole 2e is formed at a position that is more distant than additional deformable portion 2d when viewed from sealing resin 7. Through hole 2e is a hole through which a fixing member is inserted. The fixing member includes screw 10 and washer 9. Screw 10 is inserted through through hole 2e. Washer 9 is arranged to overlap with through hole 2e. Screw 10 is inserted through washer 9. In a state where screw 10 is inserted through through hole 2e, additional deformable portion 2d is arranged at a position where additional deformable portion 2d overlaps with an outer circumference of washer 9.

In this case, additional deformable portion 2d is arranged in the vicinity of the portion pressed by washer 9 of the fixing member when external connection terminal portion 2a is fixed to fixing portion 5 by the fixing member. Therefore, the stress by the fixing member can cause external connection terminal portion 2a to easily bend in additional deformable portion 2d. Therefore, breakage of sealing resin 7 and the like caused by the stress can be suppressed.

In semiconductor device 300 described above, when external connection terminal portion 2a is fixed to fixing portion 5 located outside sealing resin 7, distance L1 between fixing portion 5 and the surface of sealing resin 7 is seven times or less thickness T1 of external connection terminal portion 2a.

As described above, by applying the configuration of the semiconductor device according to the third embodiment to semiconductor device 300 in which distance L1 between fixing portion 5 and the surface of sealing resin 7 is relatively small, external connection terminal portion 2a can easily bend in additional deformable portion 2d and deformable portion 2b even when external connection terminal portion 2a and fixing portion 5 are positionally displaced. Therefore, breakage of sealing resin 7 and the like can be effectively suppressed.

In semiconductor device 300 described above, thickness T1 of external connection terminal portion 2a is equal to or greater than 0.5 mm. In this case, external connection terminal portion 2a has some degree of rigidity, and thus, when stress is applied to external connection terminal portion 2a, the stress tends to be transferred to sealing resin 7 that is in contact with lead frame 2. However, by adopting the configuration according to the present disclosure, external connection terminal portion 2a easily bends in additional deformable portion 2d and deformable portion 2b, and thus, breakage of sealing resin 7 and the like caused by the stress can be effectively suppressed.

### Fourth Embodiment

### <Configuration of Semiconductor Device>

A semiconductor device 400 shown in FIG. 16 basically has the same configuration as that of semiconductor device 100 shown in FIGS. 1 and 2. However, semiconductor device 400 shown in FIG. 16 is different from semiconductor device 100 shown in FIGS. 1 and 2 in terms of the structures of thermally conductive member 1, cooler 12 and sealing resin 7. That is, in semiconductor device 400 shown in FIG. 16, thermally conductive member 1 is constituted of insulating sheet 1b. In addition, thermally conductive member 1 and a part of cooler 12 are sealed by sealing resin 7.

Insulating sheet 1b that constitutes thermally conductive member 1 is an insulating layer having a high heat dissipation property. Insulating sheet 1b achieves electrical insulation between cooler 12 and lead frame 2. In addition, insulating sheet 1b serving as thermally conductive member 1 has the function of dissipating heat generated in semiconductor element 4 to cooler 12 through insulating sheet 1b. The same material as the material of insulating sheet 1b in semiconductor device 100 shown in FIGS. 1 and 2 can be applied as a material of insulating sheet 1b.

Sealing resin 7 covers a connection portion of lead frame 2 and thermally conductive member 1, and extends onto a side surface of cooler 12 through a connection portion of thermally conductive member 1 and cooler 12. That is, thermally conductive member 1 and a part of cooler 12 are sealed by sealing resin 7. Therefore, unlike semiconductor device 100 shown in FIG. 2, thermally conductive member 1 and cooler 12 are directly connected and fixed by sealing resin 7, without using metal foil 1a of thermally conductive member 1 and grease 11.

### Functions

Semiconductor device 400 described above includes: thermally conductive member 1; and cooler 12. Thermally conductive member 1 is connected to lead frame 2. Cooler 12 is connected to thermally conductive member 1. Thermally conductive member 1 and a part of cooler 12 are sealed by sealing resin 7.

In this case, since a part of cooler 12 connected to lead frame 2 with thermally conductive member 1 interposed therebetween is sealed by sealing resin 7, grease 11 (see FIG. 2) or the like for connecting thermally conductive member 1 and cooler 12 is unnecessary, and thus, the number of components of semiconductor device 400 can be reduced. In addition, since connection between thermally conductive member 1 and cooler 12 is also performed in the step of sealing by sealing resin 7, the manufacturing process for the semiconductor device can be simplified, as compared with when the step of sealing by sealing resin 7 and the step of connecting cooler 12 to thermally conductive member 1 are performed separately.

Also in semiconductor device 400 having the configuration, deformable portion 2d is formed in lead frame 2 similarly to semiconductor device 100 according to the first embodiment, and thus, breakage of sealing resin 7 and the like can be suppressed. As a result, semiconductor device 400 with enhanced reliability can be achieved.

In semiconductor device 400 described above, when external connection terminal portion 2a is fixed to fixing portion 5 located outside sealing resin 7, distance L1 between fixing portion 5 and the surface of sealing resin 7 is seven times or less thickness T1 of external connection terminal portion 2a.

As described above, by applying the configuration of the semiconductor device according to the fourth embodiment to semiconductor device 400 in which distance L1 between fixing portion 5 and the surface of sealing resin 7 is relatively small, lead frame 2 can easily bend in deformable portion 2b even when external connection terminal portion 2a and fixing portion 5 are positionally displaced. Therefore, breakage of sealing resin 7 and the like can be effectively suppressed.

In semiconductor device 400 described above, thickness T1 of external connection terminal portion 2a is equal to or greater than 0.5 mm. In this case, external connection terminal portion 2a has some degree of rigidity, and thus, when stress is applied to external connection terminal portion 2a, the stress tends to be transferred to sealing resin 7 that is in contact with lead frame 2. However, by adopting the configuration according to the present disclosure, breakage of sealing resin 7 and the like caused by the stress can be effectively suppressed because lead frame 2 easily bends in deformable portion 2b.

### Fifth Embodiment

The present embodiment represents application of the semiconductor device according to any one of the above-described first to fourth embodiments to a power conversion device. Although the present disclosure is not limited to a particular power conversion device, application of the present disclosure to a three-phase inverter will be described below as a fifth embodiment.

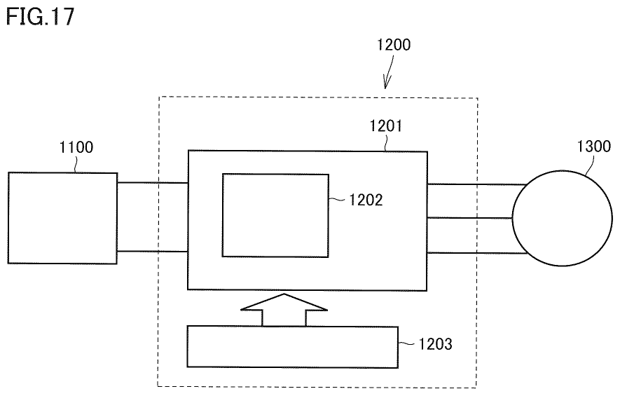

FIG. 17 is a block diagram showing a configuration of a power conversion system to which a power conversion device according to the present embodiment is applied.

The power conversion system shown in FIG. 17 is constituted of a power supply 1100, a power conversion device 1200 and a load 1300. Power supply 1100 is a DC power supply and supplies DC power to power conversion device 1200. Power supply 1100 can be configured by a variety of types, and can be configured by a DC system, a solar battery or a storage battery, for example. Power supply 1100 may be configured by a rectifier circuit or an AC/DC converter connected to an AC system. Alternatively, power supply 1100 may be configured by a DC/DC converter that converts DC power output from the DC system into prescribed power.

Power conversion device 1200 is a three-phase inverter connected between power supply 1100 and load 1300, and converts DC power supplied from power supply 1100 into AC power and supplies the AC power to load 1300. As shown in FIG. 17, power conversion device 1200 includes a main conversion circuit 1201 that converts DC power into AC power and outputs the AC power, and a control circuit 1203 that outputs, to main conversion circuit 1201, a control signal for controlling main conversion circuit 1201.

Load 1300 is a three-phase electric motor driven by the AC power supplied from power conversion device 1200. Load 1300 is not limited to a specific application, and load 1300 is an electric motor mounted on various types of electric devices and is used as an electric motor for a hybrid vehicle, an electric vehicle, a railroad vehicle, an elevator, or an air-conditioning device, for example.

Power conversion device 1200 will be described in detail below. Main conversion circuit 1201 includes a switching element and a freewheeling diode (not shown). When the switching element is switched, DC power supplied from power supply 1100 is converted into AC power, which is supplied to load 1300. While there are various types of specific circuit configurations for main conversion circuit 1201, main conversion circuit 1201 according to the present embodiment is a two-level three-phase full-bridge circuit and can be formed of six switching elements and six freewheeling diodes that are in antiparallel with the switching elements, respectively. At least one of the switching elements and the freewheeling diodes of main conversion circuit 1201 is a switching element or a freewheeling diode of semiconductor device 1202 corresponding to the semiconductor device according to any one of the above-described first to fourth embodiments. The six switching elements have every two switching elements connected in series to form upper and lower arms, and the upper and lower arms configure the full bridge circuit's phases (a U phase, a V phase and a W phase). Output terminals of the upper and lower arms, i.e., three output terminals of main conversion circuit 1201 are connected to load 1300.

In addition, main conversion circuit 1201 includes a drive circuit (not shown) that drives each switching element, and main conversion circuit 1201 may have the drive circuit built into semiconductor device 1202, or may include the drive circuit separately from semiconductor device 1202. The drive circuit generates a drive signal for driving the switching elements of main conversion circuit 1201, and supplies the drive signal to a control electrode of each switching element of main conversion circuit 1201. Specifically, in accordance with the control signal from below-described control circuit 1203, a drive signal for bringing a switching element into an on state and a drive signal for bringing a switching element into an off state are output to the control electrode of each switching element. When the switching element is maintained in the on state, the drive signal is a voltage signal (ON signal) equal to or higher than a threshold voltage of the switching element. When the switching element is maintained in the off state, the drive signal is a voltage signal (OFF signal) equal to or lower than the threshold voltage of the switching element.

Control circuit 1203 controls the switching elements of main conversion circuit 1201 such that desired power is supplied to load 1300. Specifically, control circuit 1203 calculates a time for which each switching element of main conversion circuit 1201 should be turned on (ON time) based on the power to be supplied to load 1300. For example, control circuit 1203 can control main conversion circuit 1201 by PWM control by which an ON time of a switching element is modulated in accordance with a voltage to be output. Control circuit 1203 outputs a control command (control signal) to the drive circuit of main conversion circuit 1201 such that the ON signal is output to a switching element to be turned on at each point in time and the OFF signal is output to a switching element to be turned off at each point in time. In response to this control signal, the drive circuit outputs the ON signal or the OFF signal as the drive signal to the control electrode of each switching element.

In the power conversion device according to the present embodiment, the semiconductor device according to any one of the first to fourth embodiments is applied as semiconductor device 1202 that constitutes main conversion circuit 1201, and thus, high reliability can be obtained.

Although the present embodiment has described an example where the present disclosure is applied to a two-level three-phase inverter, the present disclosure is not limited thereto, and is applicable to various power conversion devices. Although the present embodiment has described a two-level power conversion device, a three-level power conversion device or a multi-level power conversion device may be adopted, and when the power conversion device supplies power to a single-phase load, the present disclosure may be applied to a single-phase inverter. When the power conversion device supplies power to a DC load or the like, the present disclosure is also applicable to a DC/DC converter or an AC/DC converter.

The power conversion device to which the present disclosure is applied is not limited to the above case where the load is a motor. For example, the power conversion device can also be used as a power supply device for an electric discharge machine, a laser beam machine, an induction heating cooking device, or a non-contact power feeding system, and furthermore can also be used as a power conditioner for a solar power generation system, a power storage system, or the like.

It should be understood that the embodiments disclosed herein are illustrative and non-restrictive in every respect. As long as there is no contradiction, at least two of the embodiments disclosed herein may be combined. The basic scope of the present disclosure is defined by the scope of the claims, rather than the description above, and is intended to include any modifications within the scope and meaning equivalent to the scope of the claims.

### REFERENCE SIGNS LIST

1 thermally conductive member; 1a metal foil; 1b insulating sheet; 2 lead frame; 2a external connection terminal portion; 2b deformable portion; 2ba first surface; 2bb second surface; 2c inner portion; 2d additional deformable portion; 2e through hole; 3 solder; 4 semiconductor element; 5 fixing portion; 6 wire; 7 sealing resin; 7a support portion; 7b notch portion; 8 bus bar; 9 washer; 10 screw; 11 grease; 12 cooler; 21, 21a, 21b, 21c, 21d, 21e, 21f recessed portion; 100, 200, 300, 400, 1202 semiconductor device; 1100 power supply; 1200 power conversion device; 1201 main conversion circuit; 1203 control circuit; 1300 load.

1. A semiconductor device comprising:
a semiconductor element;
a lead frame having the semiconductor element mounted thereon; and
a sealing resin to seal the semiconductor element and a part of the lead frame, wherein
the lead frame includes an inner portion that is in contact with the sealing resin, and an external connection terminal portion protruding outward from a surface of the sealing resin,
the lead frame includes a deformable portion at a boundary portion between the inner portion and the external connection terminal portion, the deformable portion being configured such that stress concentrates thereon in order to cause the lead frame to bend, and
the deformable portion and the surface of the sealing resin intersect with each other,
wherein
the deformable portion includes a first surface and a second surface located opposite to the first surface, and
in the deformable portion, the sealing resin is in contact with the first surface and is not in contact with the second surface.

2. (canceled)

3. The semiconductor device according to claim 1, wherein
in a thickness direction that is a direction from the first surface to the second surface, a thickness of a portion of the sealing resin that is in contact with the first surface is 2.5 times or more a thickness of the external connection terminal portion.

4.-6. (canceled)

7. The semiconductor device according to claim 1, wherein
when the external connection terminal portion is fixed to a fixing portion located outside the sealing resin, a distance between the fixing portion and the surface of the sealing resin is seven times or less a thickness of the external connection terminal portion.

8. The semiconductor device according to claim 1, wherein
a thickness of the external connection terminal portion is equal to or greater than 0.5 mm.

9. The semiconductor device according to claim 1, comprising:
a thermally conductive member connected to the lead frame; and
a cooler connected to the thermally conductive member, wherein
the thermally conductive member and a part of the cooler are sealed by the sealing resin.

10. A power conversion device comprising:
a main conversion circuit having the semiconductor device as recited in claim 1, to convert input power and output the converted input power; and
a control circuit to output, to the main conversion circuit, a control signal for controlling the main conversion circuit.

11. A semiconductor device comprising:
a semiconductor element;
a lead frame having the semiconductor element mounted thereon; and
a sealing resin to seal the semiconductor element and a part of the lead frame, wherein
the lead frame includes an inner portion that is in contact with the sealing resin, and an external connection terminal portion protruding outward from a surface of the sealing resin,
the lead frame includes a deformable portion at a boundary portion between the inner portion and the external connection terminal portion, the deformable portion being configured such that stress concentrates thereon in order to cause the lead frame to bend, and
the deformable portion and the surface of the sealing resin intersect with each other, wherein
in the deformable portion, a recessed portion is formed such that a cross-sectional area in a cross section perpendicular to an extension direction of the external connection terminal portion is locally reduced, and
the recessed portion and the surface of the sealing resin intersect with each other.

12. A semiconductor device comprising:
a semiconductor element;
a lead frame having the semiconductor element mounted thereon; and
a sealing resin to seal the semiconductor element and a part of the lead frame, wherein
the lead frame includes an inner portion that is in contact with the sealing resin, and an external connection terminal portion protruding outward from a surface of the sealing resin,
the lead frame includes a deformable portion at a boundary portion between the inner portion and the external connection terminal portion, the deformable portion being configured such that stress concentrates thereon in order to cause the lead frame to bend, and
the deformable portion and the surface of the sealing resin intersect with each other, wherein
the external connection terminal portion includes an additional deformable portion at a position that is more distant than the deformable portion when viewed from the sealing resin, the additional deformable portion being configured such that stress concentrates thereon in order to cause the external connection terminal portion to bend.

13. The semiconductor device according to claim 12, wherein
a through hole through which a fixing member is inserted is formed in the external connection terminal portion at a position that is more distant than the additional deformable portion when viewed from the sealing resin,
the fixing member includes a screw inserted through the through hole, and a washer through which the screw is inserted, the washer being arranged to overlap with the through hole, and
in a state where the screw is inserted through the through hole, the additional deformable portion is arranged at a position where the additional deformable portion overlaps with an outer circumference of the washer.
